(19) United States
(12) Patent Application Publication
(10) Pub. No.: US 2016/0224419 A1
(43) Pub. Date: Aug. 4, 2016

(54) DEVICE AND METHOD

(71) Applicant: Kabushiki Kaisha Toshiba, Minato-ku (JP)

(72) Inventors: Yoriharu TAKAI, Hiratsuka (JP); Kenji YOSHIDA, Kamakura (JP); Susumu YAMAZAKI, Yokohama (JP); Norifumi TSUBOI, Yokohama (JP); Jun ICHISHIMA, Kamakura (JP)

(73) Assignee: Kabushiki Kaisha Toshiba, Minato-ku (JP)

(21) Appl. No.: 14/790,310

(22) Filed: Jul. 2, 2015

(30) Foreign Application Priority Data
Jan. 29, 2015 (JP) 2015-016047

(51) Int. Cl. G06F 11/10; G06F 3/06; G11C 29/52

(52) U.S. Cl. CPC G06F 11/1068; G11C 29/52; G06F 3/0619; G06F 3/064; G06F 3/0679

(57) ABSTRACT

According to one embodiment, there is provided a device including a non-volatile memory and a controller. The non-volatile memory includes a memory cell array and an internal buffer. The controller is configured to, after failure of an error correcting process of first data read from the memory cell array, store second data generated from the first data in the internal buffer and read the stored second data from the internal buffer to perform the error correcting process.

### CROSS-REFERENCE TO RELATED APPLICATIONS

This application is based upon and claims the benefit of priority from Japanese Patent Application No. 2015-016047, filed on Jan. 29, 2015; the entire contents of which are incorporated herein by reference.

### FIELD

Embodiments described herein relate generally to a device and a method.

### BACKGROUND

A device including a non-volatile memory performs error correcting process by using error correction code for correcting an error of data read from a memory cell array of the non-volatile memory. At that time, it is desired to form the device at a low cost.

### BRIEF DESCRIPTION OF THE DRAWINGS

FIG. 1 is a block diagram illustrating a configuration of a device according to a first embodiment;

FIGS. 2A and 2B are schematic diagrams illustrating an example of correction candidate data in the first embodiment;

FIGS. 3A and 3B are schematic diagrams illustrating another example of correction candidate data in the first embodiment;

FIG. 4 is a flowchart illustrating operation of the device according to the first embodiment;

FIG. 5 is a schematic diagram illustrating the operation of the device according to the first embodiment;

FIG. 6 is a flowchart illustrating operation of a device according to a second embodiment;

FIG. 7 is a schematic diagram illustrating the operation of the device according to the second embodiment;

FIG. 8 is a flowchart illustrating operation of a device according to a third embodiment;

FIG. 9 is a schematic diagram illustrating the operation of the device according to the third embodiment;

FIG. 10 is a flowchart illustrating operation of a device according to a fourth embodiment; and

FIG. 11 is a schematic diagram illustrating the operation of the device according to the fourth embodiment.

### DETAILED DESCRIPTION

In general, according to one embodiment, there is provided a device including a non-volatile memory and a controller. The non-volatile memory includes a memory cell array and an internal buffer. The controller is configured to, after failure of an error correcting process of first data read from the memory cell array, store second data generated from the first data in the internal buffer and read the stored second data from the internal buffer to perform the error correcting process.

Exemplary embodiments of a device will be explained below in detail with reference to the accompanying drawings. The present invention is not limited to the following embodiments.

### First Embodiment

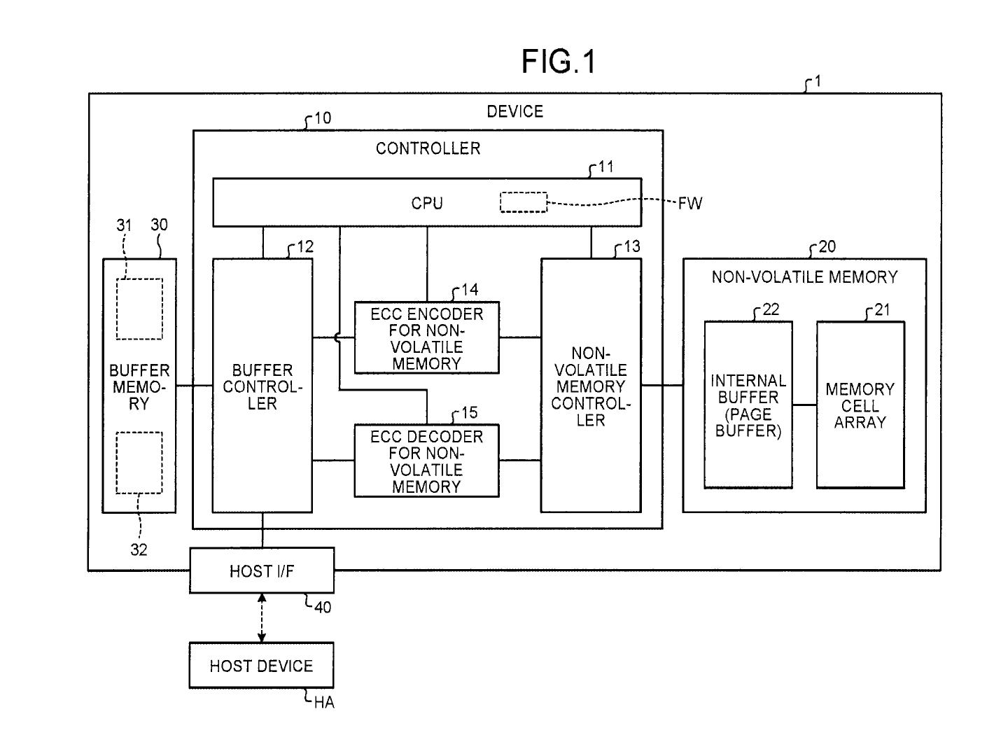

A device 1 according to a first embodiment is described with reference to FIG. 1. FIG. 1 is a block diagram illustrating a configuration of the device 1. The device 1 is externally connected to a host device HA via a communication medium to serve as an external storage medium of the host device HA. The host device HA includes a personal computer or a CPU core, for example. The device 1 includes a hard disk drive (HDD) or a solid state drive (SSD), for example.

The device 1 includes a controller 10, a non-volatile memory 20, and a buffer memory 30 as illustrated in FIG. 1.

The controller 10 integrally controls respective components of the device 1. The controller 10 includes a CPU 11, a buffer controller 12, a non-volatile memory controller 13, an ECC encoder for non-volatile memory (hereinafter, referred to as ECC encoder) 14, and an ECC decoder for the non-volatile memory (hereinafter, referred to as ECC decoder) 15.

The non-volatile memory 20 includes a memory cell array 21 and an internal buffer 22. In the memory cell array 21, a plurality of memory cells are arranged in a row direction and in a column direction. Each memory cell may realize multi-value storage by using an upper-level page and a lower-level page, for example. In the memory cell array 21, data is erased in block units while the data is written and read in page units. A block is a unit including a plurality of pages. Internal data management of the memory cell array 21 is performed by the CPU 11 in cluster units and the data is updated in sector units. In this embodiment, a page is a unit including a plurality of clusters and a cluster is a unit including a plurality of sectors. A NAND flash memory is used, for example, as the non-volatile memory 20.

It should be noted that a non-volatile memory such as a ferroelectric random access memory (FeRAM), a magnetoresistive random access memory (MRAM), a resistance random access memory (ReRAM), and a phase change random access memory (PRAM) may also be used in place of the flash memory as the non-volatile memory 20.

The internal buffer 22 is a buffer used when transfer data is transmitted/received to/from the non-volatile memory controller 13. For example, when the non-volatile memory 20 is the NAND flash memory, a size of the transfer data transmitted/received to/from the non-volatile memory controller 13 is a page size and the internal buffer 22 is a page buffer. The internal buffer 22 is formed of a static random access memory (SRAM), for example.

The buffer memory 30 includes a cache area 31 for data transfer between the host device HA and the buffer controller 12 and a working area 32 used by the CPU 11 and the buffer controller 12. The buffer memory 30 includes a dynamic random access memory (DRAM), the FeRAM, the MRAM, the PRAM or the like, for example. The buffer memory 30 temporarily stores various management tables read from the non-volatile memory 20 in the working area 32.

A host I/F 40 is an interface complying with the Peripheral Components Interconnect (PCI) Express standard, the Serial Advanced Technology Attachment (SATA) standard, the Serial Attached SCSI (SAS) standard and the like. The host I/F 40 outputs an instruction, data and the like received from the host device HA to the buffer controller 12 and transmits data input via the buffer controller 12 and response notification (notification indicating that instruction execution is completed) from the CPU 11 to the host device HA.

In the controller 10, the CPU 11 integrally controls respective components in the controller 10. The CPU 11 controls functions of the controller 10 by executing firmware FW. The functions of the controller 10 include transmission/reception of a packet, command execution, an error correction code (ECC) process, wear-leveling, and compaction, for example. When the CPU 11 receives the instruction from the host device HA via the host I/F 40 and the buffer controller 12, the CPU 11 controls according to the instruction.

The buffer controller 12 controls data transfer between the buffer memory 30 and the host device HA under the control of the CPU 11. When the buffer controller 12 receives a write instruction and the data from the CPU 11, this generates write data in which data which should be written is a data part to which a flag part is added. For example, the buffer controller 12 may include a management information identification flag for identifying whether the data which should be written is management information or user data in the flag part. The management information identification flag may be defined to be 00h(00000000b) when the data which should be written is the management information and FFh(11111111b) when the data which should be written is the user data, for example. The buffer controller 12 transfers the write data (=data part+flag part) to the ECC encoder 14.

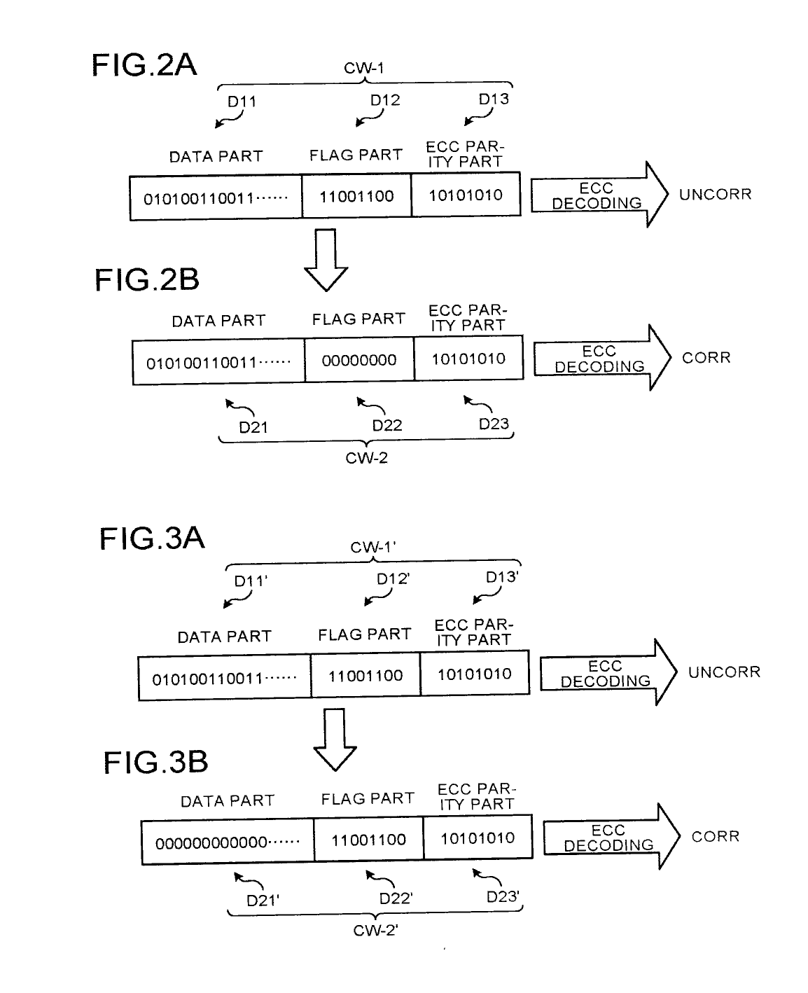

The ECC encoder 14 generates ECC parity by performing an encoding process in the ECC process on the transferred write data under the control of the CPU 11. A Hamming code, a Bose Chaudhuri Hocqenghem (BCH) code, a Reed Solomon (RS) code, a low density parity check (LDPC) code or the like is used, for example, as the ECC parity. Error correction capability of the ECC parity may be indicated by the number of correctable erroneous bits. When the error correction capability of the ECC parity is N bits (for example, 100 bits), up to N bit errors included in the write data (=data part+flag part) and an ECC parity part may be corrected by the ECC parity. The ECC encoder 14 adds the generated ECC parity to the write data as the ECC parity part to make the write data (=data part+flag part+ECC parity part) and transfers the same to the non-volatile memory controller 13 (refer to FIG. 2A).

The non-volatile memory controller 13 controls the data transfer between the non-volatile memory 20 and the buffer memory 30 under the control of the CPU 11. The non-volatile memory controller 13 issues a command for the non-volatile memory 20 and transfers the same to the non-volatile memory 20 according to an instruction received from the CPU 11.

For example, when the non-volatile memory controller 13 receives a write instruction from the CPU 11, this issues a write command to supply to the non-volatile memory 20. A command sequence of the write command is represented by following representation 1, for example.

[CMD:80h]-[ADR:col1]-[ADR:col2]-[ADR:row1]-[ADR:row2]-[ADR:row3]-[WDATA]-[CMD:10h] representation 1

In representation 1, [CMD:80h]-[ADR:col1]-[ADR:col2]-[ADR:row1]-[ADR:row2]-[ADR:row3] represents a command to write the data from the non-volatile memory controller 13 in the internal buffer 22. [WDATA] represents the write data. [CMD:10h] represents a command to program (write) from the internal buffer 22 into (in) the memory cell array 21.

The non-volatile memory 20 clears the internal buffer 22 according to the write command supplied from the non-volatile memory controller 13 and stores the data in the internal buffer 22. The non-volatile memory 20 writes the data stored in the internal buffer 22 in the memory cell array 21 in page units in general.

Alternatively, when the non-volatile memory controller 13 receives a read instruction from the CPU 11, for example, this issues a read command to supply to the non-volatile memory 20. A command sequence of the read command is represented by any one of following representations 2 to 4, for example.

[CMD:00h]-[ADR:col1]-[ADR:col2]-[ADR:row1]-[ADR:row2]-[ADR:row3]-[CMD:30h]-[CMD:00h]-[ADR:col1]-[ADR:col2]-[ADR:row1]-[ADR:row2]-[ADR:row3]-[CMD:05h]-[ADR:col1]-[ADR:col2]-[CMD:E0h]-[RDATA] representation 2

[CMD:00h]-[ADR:col1]-[ADR:col2]-[ADR:row2]-[ADR:row3]-[CMD:30h]-[CMD:05h]-[ADR:col1]-[ADR:col2]-[CMD:E0h]-[RDATA] representation 3

[CMD:00h]-[ADR:col1]-[ADR:col2]-[ADR:row2]-[ADR:row3]-[CMD:30h]-[RDATA] representation 4

In representations 2 to 4, [CMD:00h]-[ADR:col1]-[ADR:col2]-[ADR:row1]-[ADR:row2]-[ADR:row3]-[CMD:30h] represents a command to read the data from the memory cell array 21 to the internal buffer 22. In representations 2 and 3, [CMD:05h]-[ADR:col1]-[ADR:col2]-[CMD:E0h] represents a command to transfer the data from the internal buffer 22 to the non-volatile memory controller 13. [RDATA] represents read data. When being supplied with the read command represented by representation 4, the non-volatile memory 20 may also generate the read command represented by representation 3 by adding [CMD:05h]-[ADR:col1]-[ADR:col2]-[CMD:E0h].

When the non-volatile memory 20 is supplied with the read command, this reads the data reading of which is required from the memory cell array 21 to the internal buffer 22 in page units according to the read command. The non-volatile memory 20 transfers the data from the internal buffer 22 to the non-volatile memory controller 13 after the reading is completed. The non-volatile memory controller 13 transfers the data from the non-volatile memory 20 to the ECC decoder 15 according to the control by the CPU 11.

The ECC decoder 15 performs a decoding process in the ECC process on the data transferred from the non-volatile memory controller 13 (correction candidate data) under the control of the CPU 11. A data length of the correction candidate data is an ECC correction data length (CW: code word). The ECC decoder 15 performs an error correcting process of the data part and the flag part by using the ECC parity (ECC parity part) included in the correction candidate data. The error correcting process includes syndrome calculation, error position polynomial calculation and the like, for example. It is possible to detect whether there is the bit error by the syndrome calculation and obtain the number of bit errors and positions thereof by the error position polynomial calculation.

For example, when the number of bit errors is equal to or smaller than the number of correctable bits N of the ECC parity, the ECC decoder 15 performs the error correction of the data part and the flag part. At that time, the ECC decoder 15 notifies the CPU 11 that the error is correctable (CORR) and supplies the data of which error is corrected to the buffer controller 12 as the read data. The buffer controller 12 stores the read data in the cache area 31 of the buffer memory 30. The CPU 11 may use the read data stored in the cache area 31.

On the other hand, the ECC decoder 15 cannot perform the error correction of the data part and the flag part when the number of bit errors is larger than the number of correctable bits N of the ECC parity. That is to say, when the data is read from the non-volatile memory 20, if the number of generated bit errors is larger than the number of correctable bits of the ECC, the ECC decoder 15 notifies the CPU 11 that the error is uncorrectable (UNCORR). The CPU 11 is required to handle the data (correction candidate data) as invalid data.

However, when there is a bit area a correct value of which is already known or may be predicted at high probability in the correction candidate data, for example, another correction candidate data is generated by replacing a bit value of the bit area with the correct value. By an ECC re-decoding process of the other correction candidate data which is generate, the other correction candidate data might be correctable (CORR). An example of this is illustrated in FIGS. 2A and 2B and FIGS. 3A and 3B. FIGS. 2A and 2B and FIGS. 3A and 3B are views illustrating an example of the correction candidate data.

FIG. 2A illustrates correction candidate data CW-1 obtained by a first error correcting process. The correction candidate data CW-1 includes a data part D11, a flag part D12, and an ECC parity part D13. The data part D11 corresponds to the data which should be written supplied from the CPU 11 to the buffer controller 12. The flag part D12 corresponds to the flag part added to the data part. The flag part D12 includes the management information identification flag for identifying whether the data which should be written is the management information or the user data, for example. The management information identification flag may be defined to be 00h(00000000b) when the data which should be written is the management information and FFh(11111111b) when the data which should be written is the user data.

For example, a case in which the number of bit errors in the correction candidate data CW-1 is N+n, which is larger than the number of correctable bits N of the ECC parity by n is considered. In this case, if n or more bits are replaced with the correct values in the correction candidate data CW-1, it might be correctable (CORR).

At that time, the CPU 11 grasps whether the data part D11 is the management information or the user data based on control information according to the firmware FW. If the flag part D12 is a mixture of bit values 0 and bit values 1, the flag part D12 might be erroneously read or erroneously corrected. For example, the CPU 11 may replace all the bit values in the flag part D12 in the correction candidate data CW-1 with 1 (correct values) when this may grasp that the data part D11 is the user data based on the control information. Alternatively, for example, the CPU 11 may replace all the bit values in the flag part D12 in the correction candidate data CW-1 with 0 (correct values) when this may grasp that the data part D11 is the management information based on the control information.

FIG. 2B illustrates correction candidate data CW-2 generated from the correction candidate data CW-1 when the data part D11 is the management information. The correction candidate data CW-2 includes a data part D21, a flag part D22, and an ECC parity part D23. The data part D21 is the same as the data part D11 of the correction candidate data CW-1. The ECC parity part D23 is the same as the ECC parity part D13 of the correction candidate data CW-1. On the other hand, the flag part D22 is obtained by replacing all the bit values of the flag part D12 with 0 (correct values). In the case in FIG. 2B, the flag part D12 is of eight-bit length and values 1 of four bits out of eight bits are replaced with 0 to obtain the flag part D22.

Therefore, if n≦4 is satisfied, the number of bit errors in the correction candidate data CW-2 is equal to or smaller than the number of correctable bits N (for example, N=100) of the ECC parity, so that the ECC decoder 15 may perform the error correction of the data part D21 and the flag part D22. That is to say, the ECC decoder 15 performs the ECC re-decoding process (another error correcting process) on the correction candidate data CW-2. The ECC decoder 15 notifies the CPU 11 that the error is correctable (CORR) and supplies the data the error of which is corrected to the buffer controller 12 as the read data.

FIG. 3A illustrates correction candidate data CW-1′ obtained by the first error correcting process. The correction candidate data CW-1′ includes a data part D11′, a flag part D12′, and an ECC parity part D13′. The data part D11′ corresponds to the data which should be written supplied from the CPU 11 to the buffer controller 12 at the time of data writing. The data part D11′ is the management information, for example, the data of a sector bit map in a bad cluster table. The bad cluster table is the table for recording an address of the cluster which cannot be read from the memory cell array 21 in which two fields of the cluster address and the sector bit map are provided. A bit map of a plurality of bits indicating states (valid: “0”/invalid: “1”) of a plurality of sectors corresponding to each cluster address is recorded in the sector bit map.

For example, a case in which the number of bit errors in the correction candidate data CW′-1 is N+n, which is larger than the number of correctable bits N of the ECC parity by n is considered. In this case, if n or more bits are replaced with the correct values in the correction candidate data CW-1′, it might be correctable (CORR).

At that time, the CPU 11 grasps that the number of invalid sectors in a predetermined cluster is significantly smaller than the number of valid sectors based on the control information according to the firmware FW. For example, the CPU 11 grasps that the correct values of almost all the bits in the sector bit map included in the data part D11′ are 0 (valid) based on the control information. Therefore, the CPU 11 may replace all the bit values of the data part D11′ in the correction candidate data CW-1′ with 0 (values more likely to be correct).

FIG. 3B illustrates correction candidate data CW-2′ generated from the correction candidate data CW-1′ when the number of invalid sectors is significantly smaller than the number of valid sectors in a predetermined cluster. The correction candidate data CW-2′ includes a data part D21′, a flag part D22′, and an ECC parity part D23′. The flag part D22′ is the same as the flag part D12′. The ECC parity part D23′ is the same as the ECC parity part D13′. On the other hand, the data part D21′ is obtained by replacing all the bit values of the data part D11′ with 0 (values more likely to be correct). In the case in FIG. 3B, values 1 of at least six bits out of a plurality of bits of the data part D11′ are replaced with 0 to obtain the data part D21′.

Therefore, if n≦“the number of bits substantially replaced with correct values (for example, six)” is satisfied, the number of bit errors in the correction candidate data CW-2′ is equal to or smaller than the number of correctable bits N of the ECC parity, so that the ECC decoder 15 may perform the error correction of the data part D21′ and the flag part D22′. “The number of bits substantially replaced with the correct values” is obtained by subtracting the number of bits replaced with incorrect values from the number of bits replaced with the correct values, for example. That is to say, the ECC decoder 15 performs the ECC re-decoding (another error correcting process) on the correction candidate data CW-2′. The ECC decoder 15 notifies the CPU 11 that the error is correctable (CORR) and supplies the data the error of which is corrected to the buffer controller 12 as the read data.

In order to perform the ECC re-decoding process, it is required to mount a buffer not smaller than the ECC correction data length (CW: code word) in a position to which input data of the ECC decoder 15 may be supplied and temporarily hold another correction candidate data obtained by replacing the bit value in the correction candidate data in the buffer.

If the buffer for the ECC re-decoding process is provided in the non-volatile memory controller 13, the buffer which is not substantially required for programming the data into the memory cell array 21 or for reading the data from the memory cell array 21 is added. For example, the non-volatile memory controller 13 includes a write buffer for temporarily storing the data which should be programmed into the memory cell array 21 and a read buffer for temporarily storing the data on which the ECC correcting process is being performed read from the memory cell array 21. The buffer is required on a path before the input to the ECC decoder 15 for the ECC re-decoding, so that the read buffer for storing the data on which the ECC correcting process is being performed cannot be used for this. Therefore, the buffer for the ECC re-decoding process is required to be additionally mounted. According to this, when the buffer for the ECC re-decoding process is additionally mounted in the non-volatile memory controller 13, a manufacturing cost of the non-volatile memory controller 13 increases and a manufacturing cost of the device 1 might eventually increase.

Therefore, in this embodiment, it is configured that new correction candidate data generate from the correction candidate data is stored in the internal buffer 22 of the non-volatile memory 20 in the device 1. According to this, it becomes possible to perform the ECC re-decoding process without additionally mounting the buffer in the non-volatile memory controller 13.

In the non-volatile memory 20, the internal buffer 22 includes data capacity not smaller than an access unit length to the memory cell array 21 for programming/reading the data into/from the memory cell array 21. For example, when the non-volatile memory 20 is the NAND flash memory, the size of the transfer data transmitted to or received from the non-volatile memory controller 13 is the page size (or ECC correction unit) and the internal buffer 22 is the page buffer. The internal buffer 22 includes the data capacity (for example 32 to 64 KB) significantly larger than the ECC correction data length (for example, 4 KB).

The controller 10 gets access to the internal buffer 22 without direct access to the memory cell array 21 according to the firmware FW. Specifically, the non-volatile memory controller 13 may issue following commands (1) and (2) for the non-volatile memory.

The command (1) is the command to write in the internal buffer 22 without programming into the memory cell array 21 of the non-volatile memory 20 (hereinafter, referred to as a buffer write command). For example, when the non-volatile memory controller 13 receives a buffer store instruction according to the ECC re-decoding process from the CPU 11, this issues the buffer write command to the non-volatile memory 20. A command sequence of the buffer write command is represented by following representation 5, for example. According to this, it is possible to perform the ECC re-decoding process by using the internal buffer 22 (page buffer) of the non-volatile memory 20 without additionally mounting the buffer in the non-volatile memory controller 13.

[CMD:80h]-[ADR:col1]-[ADR:col2]-[ADR:row2]-[ADR:row3]-[WDATA] representation 5

The buffer write command represented by representation 5 is obtained by omitting [CMD:10h] (command to program from the internal buffer 22 into the memory cell array 21) from the write command represented by representation 1.

The non-volatile memory 20 clears the internal buffer 22 and stores the data transmitted from the non-volatile memory controller 13 in the internal buffer 22 according to the supplied buffer write command. At that time, the non-volatile memory 20 does not write the data stored in the internal buffer 22 in the memory cell array 21. That is to say, the controller 10 may write the correction candidate data generated for the ECC re-decoding in the internal buffer 22 without the access to the memory cell array 21 by using the buffer write command.

The command (2) is the command to read the data stored in the internal buffer 22 without reading from the memory cell array 21 of the non-volatile memory 20 (hereinafter, referred to as a buffer read command). For example, when the non-volatile memory controller 13 receives a buffer output instruction according to the ECC re-decoding process from the CPU 11, this issues the buffer read command to the non-volatile memory 20. A command sequence of the buffer read command is represented by following representation 6 or 7, for example.

[CMD:00h]-[ADR:col1]-[ADR:col2]-[ADR:row1]-[ADR:row2]-[ADR:row3]-[CMD:05h]-[ADR:col1]-[ADR:col2]-[CMD:E0h]-[RDATA] representation 6

[CMD:05h]-[ADR:col1]-[ADR:col2]-[CMD:E0h]-[RDATA] representation 7

The buffer read command represented by representation 6 is obtained by omitting [CMD:00h]-[ADR:col1]-[ADR:col2]-[ADR:row1]-[ADR:row2]-[ADR:row3]-[CMD:30h](command to read the data from the memory cell array 21 to the internal buffer 22) from the read command represented by representation 2. The buffer read command represented by representation 7 is obtained by omitting [CMD:00h]-[ADR:col1]-[ADR:col2]-[ADR:row1]-[ADR:row2]-[ADR:row3]-[CMD:30h] (command to read the data from the memory cell array 21 to the internal buffer 22) from the read command represented by representation 3.

The non-volatile memory 20 transfers the data the reading of which is required from the internal buffer 22 to the non-volatile memory controller 13 according to the supplied buffer read command. At that time, the non-volatile memory 20 does not read the data from the memory cell array 21 to the internal buffer 22. That is to say, the controller 10 may read the correction candidate data written in the internal buffer 22 from the internal buffer 22 without the access to the memory cell array 21 by using the buffer read command.

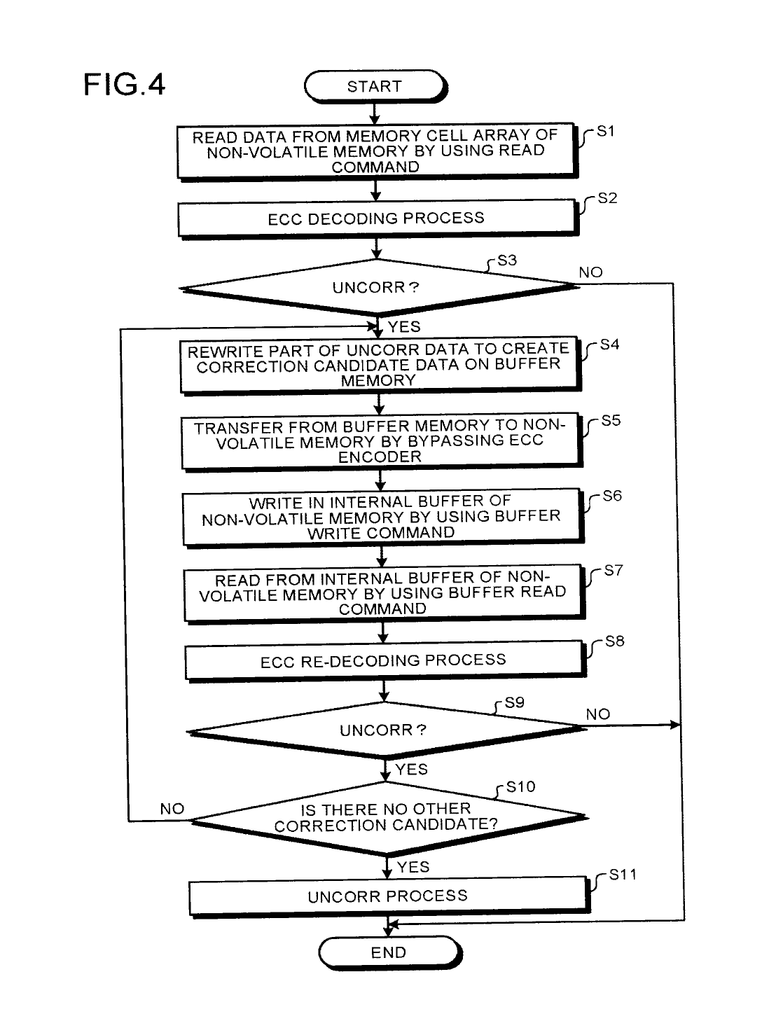

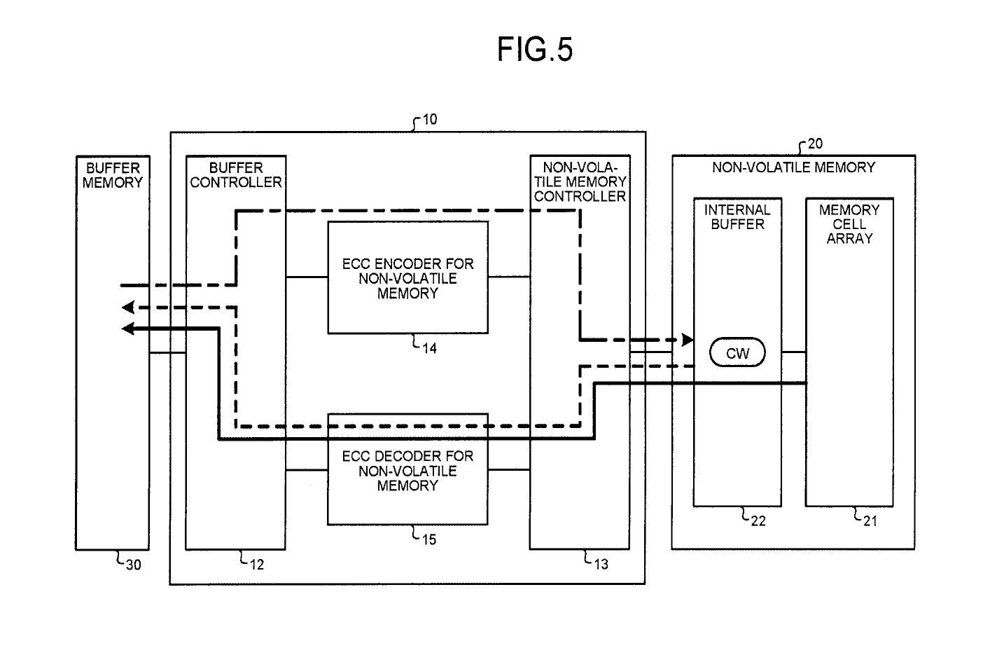

Next, operation of the device 1 is described with reference to FIGS. 4 and 5. FIG. 4 is a flowchart illustrating the operation of the device 1. FIG. 5 is a schematic diagram illustrating the operation of the device 1.

The controller 10 determines in advance a plurality of correction candidate data to which the ECC re-decoding process should be applied based on the control information according to the firmware FW (refer to FIGS. 2A and 2B and FIGS. 3A and 3B).

The controller 10 issues the read command according to a read request from the host device HA, a request from the firmware FW or the like. The controller 10 reads the data (correction candidate data CW-1) from the memory cell array 21 of the non-volatile memory 20 via the internal buffer 22 by using the issued read command (S1: refer to solid arrow in FIG. 5). The controller 10 transfers the read correction candidate data CW-1 to the ECC decoder 15 via the non-volatile memory controller 13 (refer to solid arrow in FIG. 5). The controller 10 performs the ECC decoding process on the correction candidate data CW-1 by the ECC decoder 15 (S2).

The controller 10 determines whether or not the error is uncorrectable (UNCORR) as a result of the ECC decoding process (S3). The controller 10 determines that the ECC decoding process is successful, that is to say, the error is uncorrectable (“No” at S3) when the number of bit errors detected in the correction candidate data CW-1 is equal to or smaller than the number of correctable bits N of the ECC parity. The controller 10 transfers the correction candidate data CW-1 to the buffer memory 30 via the buffer controller 12 (refer to solid arrow in FIG. 5) and finishes the procedure.

On the other hand, the controller 10 determines that the ECC decoding process is unsuccessful, that is to say, the error is uncorrectable (“Yes” at S3) when the number of bit errors detected in the correction candidate data CW-1 is larger than the number of correctable bits N of the ECC parity. The controller 10 transfers the correction candidate data CW-1 to the buffer memory 30 via the buffer controller 12 (refer to solid arrow in FIG. 5).

Then, the controller 10 selects one of a plurality of correction candidate data determined in advance and generates new correction candidate data based on the selected correction candidate data. That is to say, the controller 10 rewrites the bit value of a partial bit area of the correction candidate data CW-1 with the correct value or the value more likely to be correct (refer to FIGS. 2A and 2B and FIGS. 3A and 3B) to generate the new correction candidate data CW-2 from the correction candidate data CW-1 on the buffer memory 30 based on the control information according to the firmware FW (S4).

The controller 10 transfers the generate correction candidate data CW-2 from the buffer memory 30 to the non-volatile memory 20 via the buffer controller 12, the ECC encoder 14, and the non-volatile memory controller 13. At that time, the controller 10 controls such that the ECC encoding process by the ECC encoder 14 is not performed and transfers the correction candidate data CW-2 to the non-volatile memory 20 substantially bypassing the ECC encoder 14 (refer to dashed-dotted arrow in FIG. 5) (S5). The controller 10 writes the correction candidate data CW-2 in the internal buffer 22 of the non-volatile memory 20 by using the buffer write command (S6: refer to dashed-dotted arrow in FIG. 5).

Thereafter, the controller 10 reads the correction candidate data CW-2 from the internal buffer 22 of the non-volatile memory 20 by using the buffer read command (S7). The controller 10 transfers the read correction candidate data CW-2 to the ECC decoder 15 via the non-volatile memory controller 13 (refer to broken arrow in FIG. 5). The controller 10 performs the ECC re-decoding process on the correction candidate data CW-2 by the ECC decoder 15 (SB).

The controller 10 determines whether or not the error is uncorrectable (UNCORR) as a result of the ECC decoding process (S9). When the number of bit errors detected in the correction candidate data CW-2 is equal to or smaller than the number of correctable bits N of the ECC parity, the controller 10 determines that the error is correctable (“No” at S9) and transfers the correction candidate data CW-2 to the buffer memory 30 via the buffer controller 12 (refer to broken arrow in FIG. 5) to finish the procedure.

When the number of bit errors detected in the correction candidate data CW-2 is larger than the number of correctable bits N of the ECC parity, the controller 10 determines that the error is uncorrectable (“Yes” at S9) and transfers the correction candidate data CW-2 to the buffer memory 30 via the buffer controller 12 (refer to broken arrow in FIG. 5). Then, the controller 10 determines whether or not there is no correction candidate data not yet selected out of a plurality of correction candidate data determined in advance (S10). The controller 10 returns the procedure to S4 when there is the correction candidate data not yet selected (“No” at S10) or performs an error process of uncorrectable error (UNCORR process) (311) to finish the procedure when there is no correction candidate data not yet selected (“Yes” at S10).

As described above, in the device 1 of the first embodiment, when the ECC decoding process (error correcting process) of the correction candidate data CW-1 is unsuccessful, the controller 10 stores another correction candidate data CW-2 generate from the correction candidate data CW-1 in the internal buffer 22. For example, the controller 10 rewrites the correction candidate data CW-1 to generate another correction candidate data CW-2 on the buffer memory 30 and transfers the correction candidate data CW-2 from the buffer memory 30 to the internal buffer 22 to write therein. Then, the controller 10 reads the correction candidate data CW-2 from the internal buffer 22 to perform the error correcting process (ECC re-decoding process). According to this, it is possible to perform the ECC re-decoding process without additionally mounting the buffer for the ECC re-decoding process in the controller 10 (in the non-volatile memory controller 13), so that the device 1 which performs the ECC re-decoding process may be formed at a low cost.

Herein, a case in which the controller 10 writes the correction candidate data CW-2 in the memory cell array 21 via the internal buffer 22 is considered. In this case, it takes time from the transfer by the controller 10 of the correction candidate data CW-2 to the memory cell array 21 of the non-volatile memory 20 to the reading of the same from the memory cell array 21 of the non-volatile memory 20, so that processing time of the ECC re-decoding process might be long.

In contrast, in the first embodiment, the controller 10 writes the correction candidate data CW-2 in the internal buffer 22 without the access to the memory cell array 21 by using the buffer write command in the device 1. The controller 10 reads the correction candidate data CW-2 from the internal buffer 22 without the access to the memory cell array 21 by using the buffer read command.

According to this, it is possible to easily shorten the time from the transfer by the controller 10 of the correction candidate data CW-2 to the non-volatile memory 20 to the reading of the same from the non-volatile memory 20, so that it is possible to easily shorten the processing time of the ECC re-decoding process.

### Second Embodiment

A device 1 according to a second embodiment is next described. A portion different from the first embodiment is hereinafter mainly described.

In the first embodiment, correction candidate data CW-1 is rewritten to generate another correction candidate data CW-2 on a buffer memory 30. However, the correction candidate data CW-1 is rewritten to generate another correction candidate data CW-2 on an internal buffer 22 in the second embodiment.

Specifically, a non-volatile memory controller 13 may issue a following command (3) for a non-volatile memory in a controller 10 of the device 1.

The command (3) is the command to overwrite a part of data stored in the internal buffer 22 without programming into a memory cell array 21 of a non-volatile memory 20 (hereinafter, referred to as a buffer overwrite command). For example, when the non-volatile memory controller 13 receives a buffer rewrite instruction according to an ECC re-decoding process, this issues the buffer overwrite command to supply to the non-volatile memory 20. A command sequence of the buffer write command is represented by following representation 8 or 9, for example. According to this, it is possible to rewrite the correction candidate data CW-1 to generate new correction candidate data CW-2 on the internal buffer 22 of the non-volatile memory 20, so that transfer time of the correction candidate data CW-2 from the buffer memory 30 to the non-volatile memory 20 may be reduced.

[CMD:85h]-[ADR:col1]-[ADR:col2]-[ADR:row2]-[ADR:row3]-[WDATA] representation 8

[CMD:85h]-[ADR:col1]-[ADR:col2]-[WDATA] representation 9

The non-volatile memory 20 overwrites to store data transmitted from the non-volatile memory controller 13 in a position an address of which is specified in the internal buffer 22 without clearing the internal buffer 22 according to the supplied buffer overwrite command. The internal buffer 22 may have a one-bit length in a row direction and a predetermined bit length (for example, page size) in a column direction. The position in which the data is overwritten to be stored may be specified by description of a column address [ADR:col1]-[ADR:col2] in the command, for example. At that time, the non-volatile memory 20 does not write the data stored in the internal buffer 22 in the memory cell array 21. That is to say, the controller 10 may rewrite the correction candidate data CW-1 to generate another correction candidate data CW-2 on the internal buffer 22 without access to the memory cell array 21 by using the buffer overwrite command.

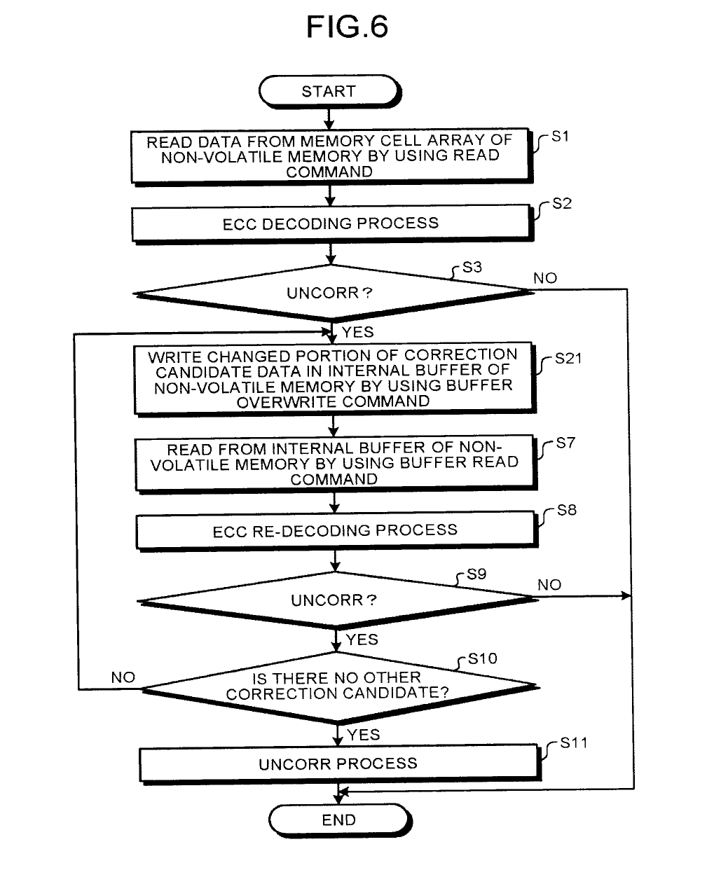

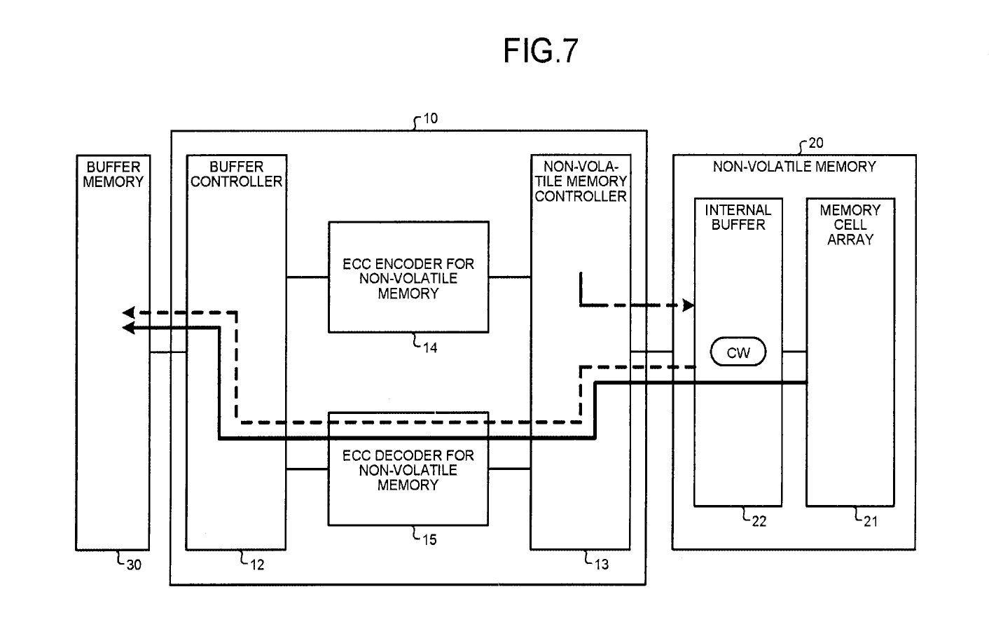

More specifically, the device 1 performs operation illustrated in FIGS. 6 and 7 in place of operation illustrated in FIGS. 4 and 5. FIG. 6 is a flowchart illustrating another operation of the device 1.

FIG. 7 is a schematic diagram illustrating another operation of the device 1.

In the operation illustrated in FIG. 6, step S21 is performed in place of steps S4 to S6 (refer to FIG. 4).

At step S21, one of a plurality of correction candidate data determined in advance is selected and the selected correction candidate date is generate. That is to say, the correction candidate data CW-1 read at S1 is still stored in the internal buffer 22 unless a write command or a buffer write command is supplied to the non-volatile memory 20 in a period from S1 to S21 (FIG. 7).

Therefore, the controller 10 may rewrite a part of bit values of the correction candidate data CW-1 with a correct value or a value more likely to be correct on the internal buffer 22 based on control information according to firmware FW (refer to FIGS. 2A and 2B and FIGS. 3A and 3B). At that time, the controller 10 gets access to a changed portion of the correction candidate data CW-1 in the internal buffer 22 and selectively rewrites the changed portion by overwriting by using the buffer overwrite command (refer to dashed-dotted arrow in FIG. 7). According to this, the controller 10 generates the new correction candidate data CW-2 from the correction candidate data CW-1 on the internal buffer 22.

As described above, in the device 1 according to the second embodiment, when an ECC decoding process (error correction decoding process) of the correction candidate data CW-1 is unsuccessful, the controller 10 rewrites the correction candidate data CW-1 to generate another correction candidate data CW-2 on the internal buffer 22. According to this, time for data transfer from the buffer memory 30 to the non-volatile memory 20 may be reduced (refer to dashed-dotted arrow in FIG. 7) and processing time of the ECC re-decoding process may be further shortened.

In the second embodiment, the controller 10 writes the correction candidate data CW-2 in the internal buffer 22 without the access to the memory cell array 21 by using the buffer overwrite command in the device 1. The controller 10 rewrites the correction candidate data CW-1 to generate the correction candidate data CW-2 on the internal buffer 22 without the access to the memory cell array 21 by using a buffer read command. According to this, it is possible to easily shorten time from a rewrite request by the controller 10 to the reading of the correction candidate data CW-2 from the non-volatile memory 20, so that it is possible to easily shorten the processing time of the ECC re-decoding process.

### Third Embodiment

A device 1 according to a third embodiment is next described. A portion different from the first embodiment is hereinafter mainly described.

Although an ECC re-decoding process is sequentially performed on a plurality of correction candidate data determined in advance in the first embodiment, the ECC re-decoding process is collectively performed on a plurality of correction candidate data determined in advance in the third embodiment.

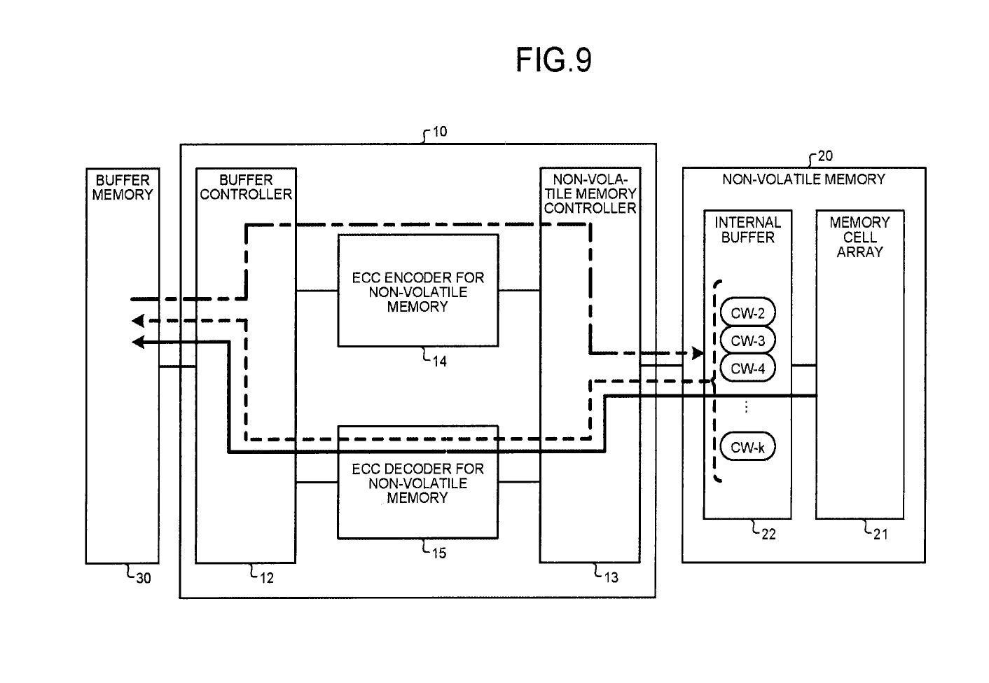

Specifically, in a non-volatile memory 20 in the device 1, an internal buffer 22 has data capacity larger than an ECC correction data length. That is to say, the internal buffer 22 has the data capacity in which a plurality of correction candidate data may be stored. Therefore, a controller 10 may rewrite correction candidate data CW-1 to generate a plurality of correction candidate data CW-2 to CW-k on a buffer memory 30 and transfer a plurality of correction candidate data CW-2 to CW-k from the buffer memory 30 to the internal buffer 22 to store (refer to FIG. 9).

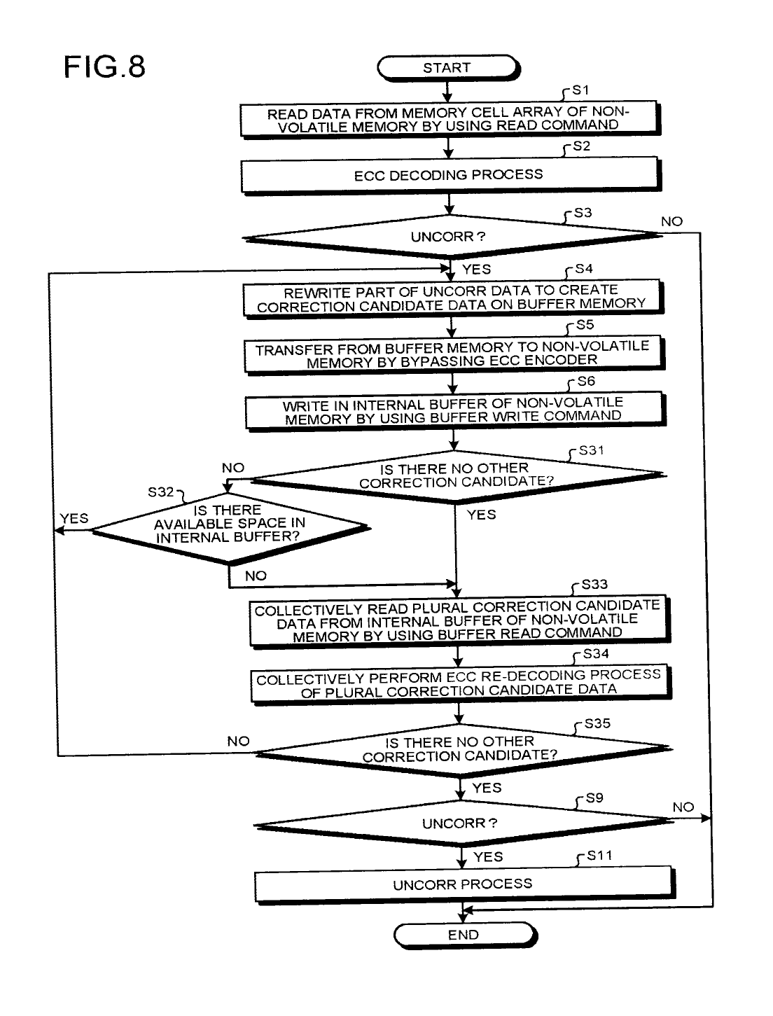

More specifically, the device 1 performs operation illustrated in FIGS. 8 and 9 in place of operation illustrated in FIGS. 4 and 5. FIG. 8 is a flowchart illustrating operation of the device 1. FIG. 9 is a schematic diagram illustrating the operation of the device 1.

In the operation illustrated in FIG. 8, steps S31 to S35 are performed in place of steps S7, S8, and S10 (refer to FIG. 4).

At step S31, the controller 10 determines whether or not there is no correction candidate data not yet selected out of a plurality of correction candidate data determined in advance. When there is the correction candidate data not yet selected (“No” at S31), the controller 10 checks whether or not there is an available space in the internal buffer 22 (S32), and if there is the available space (“Yes” at S32), this returns the procedure to S4. According to this, a loop from S4 to S32 is repeated and a plurality of correction candidate data CW-2 to CW-k is stored in the internal buffer 22 (refer to FIG. 9).

When there is no more correction candidate data not yet selected (“Yes” at S31) or when there is no more available space in the internal buffer 22 (“No” at S32), the controller 10 collectively reads a plurality of correction candidate data CW-2 to CW-k from the internal buffer 22 of the non-volatile memory 20 by using a buffer read command (S33). The controller 10 collectively transfers a plurality of read correction candidate data CW-2 CW-k to an ECC decoder 15 via a non-volatile memory controller 13 (refer to broken arrow in FIG. 9). According to this, the controller 10 collectively performs the ECC re-decoding process on a plurality of correction candidate data CW-2 to CW-k by the ECC decoder 15 (S34).

Then, the controller 10 determines whether or not there is no correction candidate data not yet selected out of a plurality of correction candidate data determined in advance (S35). The controller 10 returns the procedure to S4 when there is the correction candidate data not yet selected (“No” at S35) or shifts the procedure to S9 when there is no correction candidate data not yet selected (“Yes” at S35).

As described above, in the third embodiment, the controller 10 sequentially performs the processes of generating a plurality of correction candidate data CW-2 to CW-k on the buffer memory 30 and transferring the same from the buffer memory 30 to the internal buffer 22 to store in the device 1. Then, the controller 10 collectively reads a plurality of correction candidate data CW-2 to CW-k from the internal buffer 22 to perform an error correcting process. According to this, it is possible to reduce overhead in the transferring process and the error correcting process of the correction candidate data, so that processing time of the error correcting process of a plurality of correction candidate data CW-2 to CW-k may be easily shortened.

### Fourth Embodiment

A device 1 according to a fourth embodiment is next described. A portion different from the second embodiment is hereinafter mainly described.

Although an ECC re-decoding process is sequentially performed on a plurality of correction candidate data determined in advance in the second embodiment, the ECC re-decoding process is collectively performed on a plurality of correction candidate data determined in advance in the fourth embodiment.

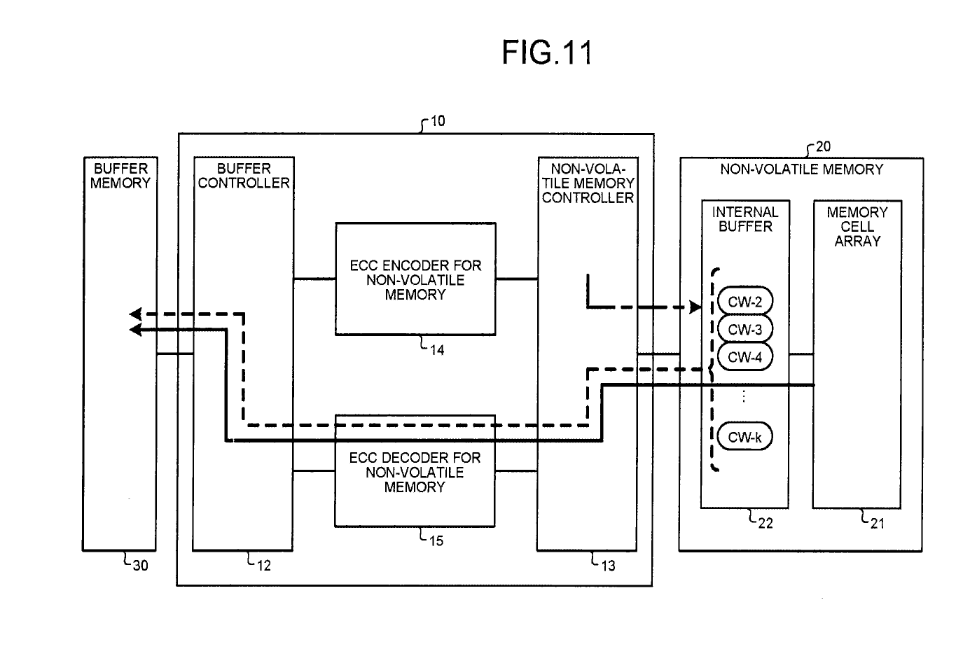

Specifically, in a non-volatile memory 20 in the device 1, an internal buffer 22 has data capacity larger than an ECC correction data length. That is to say, the internal buffer 22 has the data capacity in which a plurality of correction candidate data may be stored. Therefore, the controller 10 may rewrite correction candidate data CW-1 to generate a plurality of correction candidate data CW-2 to CW-k on the internal buffer 22 (refer to FIG. 11).

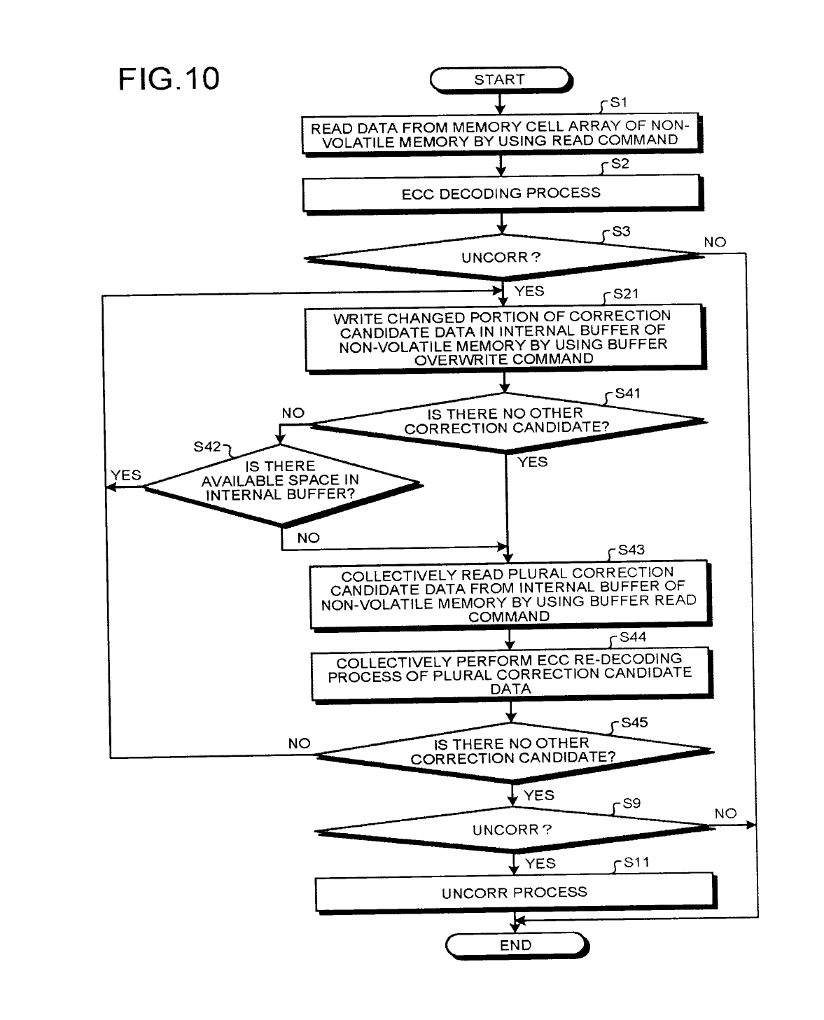

More specifically, the device 1 performs operation illustrated in FIGS. 10 and 11 in place of operation illustrated in FIGS. 6 and 7. FIG. 10 is a flowchart illustrating the operation of the device 1. FIG. 11 is a schematic diagram illustrating the operation of the device 1.

In the operation illustrated in FIG. 10, steps S41 to S45 are performed in place of steps S7, S8, and S10 (refer to FIG. 6).

At step S41, the controller 10 determines whether or not there is no correction candidate data not yet selected out of a plurality of correction candidate data determined in advance. When there is the correction candidate data not yet selected (“No” at S41), the controller 10 checks whether or not there is an available space in the internal buffer 22 (S42), and if there is the available space (“Yes” at S42), this returns the procedure to S21. At S21, the controller 10 generates a copy of any one of already generate correction candidate data by using a buffer overwrite command for generating new correction candidate data separately from the already generate correction candidate data. The controller 10 writes the copied correction candidate data in the available space of the internal buffer 22 and selectively rewrites a changed portion in the copied correction candidate data by overwriting. According to this, a loop from S21 to S42 is repeated and a plurality of correction candidate data CW-2 to CW-k is generate on the internal buffer 22 (refer to FIG. 11).

When there is no more correction candidate data not yet selected (“Yes” at S41) or when there is no more available space in the internal buffer 22 (“No” at S42), the controller 10 collectively reads a plurality of correction candidate data CW-2 to CW-k from the internal buffer 22 of the non-volatile memory 20 by using a buffer read command (S43). The controller 10 collectively transfers a plurality of read correction candidate data CW-2 CW-k to an ECC decoder 15 via a non-volatile memory controller 13 (refer to broken arrow in FIG. 11). According to this, the controller 10 collectively performs the ECC re-decoding process on a plurality of correction candidate data CW-2 to CW-k by the ECC decoder 15 (S44).

Then, the controller 10 determines whether or not there is no correction candidate data not yet selected out of a plurality of correction candidate data determined in advance (S45). The controller 10 returns the procedure to S21 when there is the correction candidate data not yet selected (“No” at S45) or shifts the procedure to S9 when there is no correction candidate data not yet selected (“Yes” at S45).

As described above, in the fourth embodiment, the controller 10 sequentially performs the processes of generating a plurality of correction candidate data CW-2 to CW-k on the internal buffer 22 in the device 1. Then, the controller 10 collectively reads a plurality of correction candidate data CW-2 to CW-k from the internal buffer 22 to perform an error correcting process. According to this, it is possible to reduce overhead in the transferring process and the error correcting process of the correction candidate data, so that processing time of the error correcting process of a plurality of correction candidate data CW-2 to CW-k may be easily shortened.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A device comprising:
a non-volatile memory including a memory cell array and an internal buffer; and
a controller configured to, after failure of an error correcting process of first data read from the memory cell array, store second data generated from the first data in the internal buffer and read the stored second data from the internal buffer to perform the error correcting process.

2. The device according to claim 1, wherein
the controller is configured to rewrite a part of bits in the first data to generate the second data.

3. The device according to claim 2, wherein
the controller is configured to rewrite the part of bits based on a correct value of the part of bits or a value more likely to be correct than the part of bits.

4. The device according to claim 1, wherein
the first data comprises a first part and a second part, and
the controller is configured to rewrite at least one of the first part and the second part in the first data to generate the second data.

5. The device according to claim 4, wherein
the controller is configured to rewrite at least one of the first part and the second part based on a correct value of at least one of the first part and the second part or a value more likely to be correct than at least one of the first part and the second part.

6. The device according to claim 1, wherein
the controller is configured to generate the second data from the first data to write the generated second data in the internal buffer.

7. The device according to claim 1, wherein
the controller is configured to write the second data in the internal buffer without access to the memory cell array.

8. The device according to claim 1, wherein
the controller is configured to read the written second data from the internal buffer without access to the memory cell array.

9. The device according to claim 1, further comprising:
a buffer memory, wherein
the controller is configured to rewrite the first data on the buffer memory to generate the second data and transfer the second data from the buffer memory to the internal buffer.

10. The device according to claim 9, wherein
the controller is configured to rewrite the first data on the buffer memory to generate a plurality of second data to transfer the generated second data from the buffer memory to the internal buffer.

11. The device according to claim 10, wherein
the controller is configured to collectively read the plurality of second data from the internal buffer to perform the error correcting process.

12. The device according to claim 1, wherein
the controller is configured to rewrite the first data on the internal buffer to generate the second data.

13. The device according to claim 1, wherein
the controller is configured to rewrite the first data on the internal buffer without access to the memory cell array to generate the second data.

14. The device according to claim 1, wherein
the controller is configured to rewrite the first data on the internal buffer to generate a plurality of second data.

15. The device according to claim 14, wherein
the controller is configured to read the plurality of second data from the internal buffer to perform the error correcting process.

16. A method comprising:
performing an error correcting process of first data read from a memory cell array of a non-volatile memory including an internal buffer;
storing second data generated from the first data in the internal buffer after failure of the error correcting process of the first data; and
reading the stored second data from the internal buffer to perform the error correction decoding process.

17. The method according to claim 16, wherein
storing the second data in the internal buffer comprises generating the second data from the first data to write the generated second data in the internal buffer.

18. The method according to claim 16, wherein
generating the second data from the first data comprises rewriting a part of bits in the first data to generate the second data.

19. The method according to claim 16, wherein
storing the second data in the internal buffer comprises rewriting the first data on the internal buffer to generate the second data.

20. The method according to claim 16, wherein
the first data comprises a first part and a second part, and
generating the second data from the first data comprises rewriting at least one of the first part and the second part in the first data to generate the second data.
